(19) United States
(12) Patent Application Publication
(10) Pub. No.: US 2011/0239071 A1
(43) Pub. Date: Sep. 29, 2011

(54) DETERMINATION APPARATUS, DETERMINATION SYSTEM, DETERMINATION METHOD, AND RECORDING MEDIUM

(75) Inventors: Hiroyasu SUGANO, Kawasaki (JP); Shinichi SHIOTSU, Kawasaki (JP)

(73) Assignee: Fujitsu Limited, Kawasaki (JP)

(21) Appl. No.: 13/069,819

(22) Filed: Mar. 23, 2011

(30) Foreign Application Priority Data
Mar. 26, 2010 (JP) 2010-072902

(51) Int. Cl. H03M 13/00; G06F 11/07

(52) U.S. Cl. 714/746; 714/E11.023

(57) ABSTRACT

A determination apparatus includes a data obtaining unit that obtains data from a detector that outputs data in time series, in accordance with the result of detection of a detection target; a data correction unit that compares reference data indicative of data to be outputted by the detector when the detection target passed through a specific area with the data obtained by the data obtaining unit, and corrects the data obtained by the data obtaining unit so that the data length thereof is equal to the data length of the reference data; a similarity determination unit that determines the similarity between the data corrected by the data correction unit and the reference data; and a determination unit that determines whether the detection target passed through the specific area or not based on the result of the determination by the similarity determination unit.

### CROSS-REFERENCE TO RELATED APPLICATIONS

This application is based upon and claims the benefit of priority of the prior Japanese Patent Application No. 2010-72902 filed on Mar. 26, 2010, the entire contents of which are incorporated herein by reference.

### FIELD

The present application relates to a determination apparatus, a determination system, a determination method and a recording medium for determining an IC tag passage area.

### BACKGROUND

In recent years, RFID (radio frequency identification) has been used in various fields. RFID is a technology of reading data containing specific identification information stored in IC (integrated circuit) tags and writing data to IC tags by radio communication.

RFID includes: an active type in which tags incorporate a battery and are internally supplied with power for operation; and a passive type in which tags incorporate no battery and operate on power supplied by a high frequency transmitted from a reader device.

The passive type incorporating no battery can be comparatively inexpensively provided compared with the active type, and are therefore expected to be used in a variety of areas including the field of physical distribution.

When the UHF band (860 to 960 MHz) is used as the frequency band of RFID, even the passive type includes a wide reading range compared with when other frequency bands are used, and a plurality of tags can be read at a time. Consequently, for example, in the field of physical distribution, a plurality of tags attached to a multiplicity of articles can be read at a time for inspection.

However, when the reading range is increased by using the UHF band, there are cases where the information of a tag not intended by the administrator is read. For example, in inspections of articles at the time of arrival and shipment in a warehouse or the like, there are cases where the information of a tag of an article placed in a position that is so far from the inspection gate that the tag cannot be read under normal conditions is read by radio waves reflected from a forklift or the like passing near the article. Moreover, when a plurality of gates are placed side by side, there is a possibility that the tag of an article entering an adjoining gate is read, so that an erroneous determination can occur.

In such cases, there are cases where an unnecessary tag can be excluded by performing filtering based on the structure of the ID stored in the tag. As an example, when the structure of the IDs are hierarchized according to the types of the articles (for example, whether the type of an article is a pallet or an individual article), a tag ID representing a pallet tag can be excluded by being previously informed of the type data representing the types of the articles.

However, when a target tag and an unnecessary tag are attached to the same type of articles, it is impossible to discriminate between them according to the type data contained in the hierarchized IDs.

For cases such as when the unintentional tag reading is due to the radio wave reflection, a method is known in which detection is periodically performed a plurality of times on the tags attached to articles and when the ID of a tag cannot continuously be detected a predetermined number of times or more, the tag is excluded as a tag accidentally read because of the reflection (see, for example, Japanese Laid-open Patent Publication No. 2005-275960).

Another method is to physically isolate the reading range by a radio wave absorbing plate or the like to avoid unintentional tag reading. However, with this method, there is a problem in that the number of man-hours at the installation site increases.

Still another method is to find tags situated outside the proper reading range by using an antenna whose directivity can be changed such as a phased-array type and regard the tags as unnecessary tags. However, with this method, a problem newly arises in that the price of the reading device increases.

To solve these problems, the inventors of the present application disclosed in a previous application a method in which, in a reader (reading device) that repetitively reads data from a tag in a communication possible area in a non-contact manner and a control system, a result of clustering from the previously collected time-series data of the reading results according to the similarity provided on the time-series data is provided as reference data and the read data is classified into necessary data and unnecessary data by calculating the similarity to the reference data (see, for example, Japanese Laid-open Patent Publication No. 2010-123086 and International Publication Pamphlet No. WO2010/106573).

However, the method of the previous application in which the read data is classified into necessary data and unnecessary data by comparing the read data with the reference data is based on a premise that the reading conditions (the number of tags, the movement speed, etc.) are the same between at the time of reference data collection and at the time of operation. This is because when the reading conditions are different between at the time of reference data collection and at the time of operation, the time-series data of the reading results to be compared varies and this degrades the determination accuracy.

For example, at the time of operation, when a set of articles the number of tags of which is approximately twice as large as that at the time of reference data collection is moved at the same movement speed as that at the time of reference data collection, it is considered that the number of times the same tag is read decreases approximately by half. In other words, under this condition, while the time for which the tags remain in the communication range of the antenna is substantially the same as that at the time of reference data collection, the number of tags read by one search is twice, so that the response time for the completion of one search also requires approximately twice. Consequently, the number of times of search execution during the time for which the tags remain in the communication range of the antenna is approximately half that at the time of reference data collection.

In such a case, since the length of the time-series data of the reading result is approximately half and the similarity to the reference data is decreased, there are cases where a tag that may be determined as necessary under normal situation is determined as unnecessary and a tag that may be determined as unnecessary under normal situation is determined as necessary.

Further, a problem arises also when there is a difference in the movement speed when articles with tags are conveyed. When the movement speed is different between at the time of reference data collection and at the time of operation, the time for which the tags remain in the communication range of the antenna varies, so that the number of times of reading varies.

In such a case, the similarity to the reference data is affected and this can degrade the determination accuracy.

It is considered that the actual operation is often performed under reading conditions different from those at the time of previously performed reference data collection, and the degradation in determination accuracy in such a case is a significant problem.

### SUMMARY

A determination apparatus disclosed in the present application includes: a data obtaining unit that obtains data from a detector that outputs data in time series, in accordance with a result of detection of a detection target, a data correction unit that compares reference data indicative of data to be outputted by the detector when the detection target passed through a specific area with the data obtained by the data obtaining unit, and corrects the data obtained by the data obtaining unit so that a data length of the data is equal to a data length of the reference data, a similarity determination unit that determines a similarity between the data corrected by the data correction unit and the reference data, and a determination unit that determines whether the detection target passed through the specific area or not based on a result of the determination by the similarity determination unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic view depicting the general structure of an IC tag reading system according to a first embodiment;

FIG. 2 is a schematic view of assistance in explaining concrete examples of determination areas;

FIG. 3 is a block diagram of assistance in explaining the hardware structures of a host server and a reader;

FIG. 4 is a block diagram of assistance in explaining the functional structures of the host server and the reader;

FIGS. 5A and 5B are schematic views depicting examples of reading patterns;

FIG. 6 is a schematic view depicting an example of the average number of times of reading for each antenna;

FIG. 7 is a flowchart depicting a reference data generation procedure;

FIG. 8 is a flowchart depicting a tag reading procedure at the time of operation;

FIG. 9 is a flowchart depicting a normalization procedure;

FIG. 10 is a flowchart depicting a reading pattern extension procedure; and

FIG. 11 is a block diagram of assistance in explaining the functional structures of a host server and a reader according to a third embodiment.

### DESCRIPTION OF EMBODIMENTS

Hereinafter, embodiments in which a determination system of the present application is applied to an IC tag reading system will concretely be described by using the drawings.

### First Embodiment

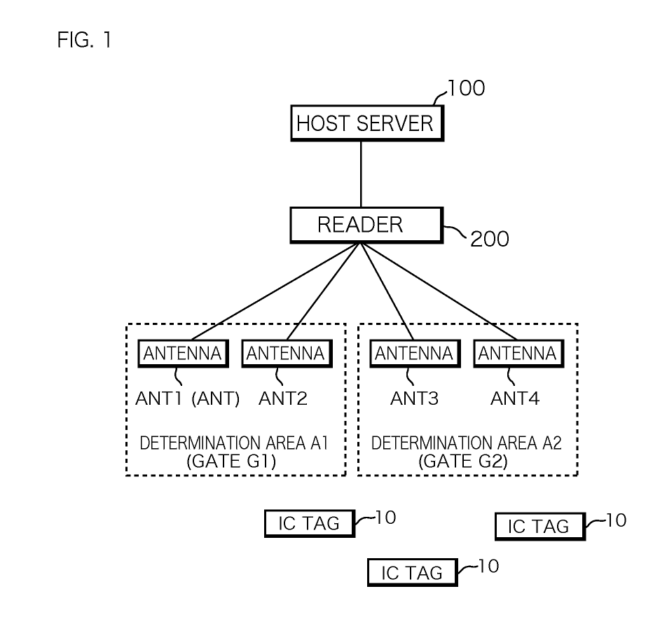

FIG. 1 is a schematic view depicting the general structure of an IC tag reading system according to a first embodiment. The IC tag reading system according to the first embodiment includes a host server 100, a reader 200, antennas ANT1 to ANT4 and IC tags 10.

In the following description, the antennas ANT1 to ANT4 will be designated as antennas ANT when it is unnecessary to distinguish among them in describing them.

The host server 100 integrates the information of the IC tags 10 read by the reader 200, and passes it to an business application.

The host server 100 and the reader 200 are connected by a wired or wireless LAN, WAN or other networks. A plurality of antennas ANT are connected to the reader 200, and the reader 200 performs data transmission and reception with the IC tags 10 by performing transmission and reception of commands and responses by radio communication via the antennas ANT.

The transmission and reception of commands and responses is performed according to a predetermined protocol. For example, as a standard protocol for UHF IC tags using a communication frequency band of 860 to 960 MHz, a standard such as ISO18000-6 Type C is used.

The reader 200 autonomously operates, and repetitively performs reading of the IC tags 10 according to pre-provided conditions. When reading the IC tags 10, the reader 200 communicates with one or more than one IC tag 10 situated within the reach of radio waves at a constant radio field intensity from the connected antennas ANT. The reader 200 returns the data received from the IC tags 10, to the host server 100 at a pre-provided time.

The host server 100 processes the data transmitted from the reader 200 according to a pre-provided program.

The IC tags 10 each include a memory storing specific identification data (identifier, hereinafter referred to as ID), an IC chip that executes predetermined processing and an antenna that enables radio communication. The IC tags 10 are attached to articles or persons to be identified by IDs. Moreover, the IC tags 10 may store data related to the article or the person to which they are attached (for example, the kind and manufacturing date of the article).

The IC tags 10 described in the present embodiment are of a radio wave type using the UHF communication frequency band, and generates current by receiving a high frequency transmitted from the antennas ANT of the reader 200. The generated current is rectified and then, supplied to the parts of the IC tags 10 as an adjusted supply voltage, which makes the IC tags 10 operable.

While the above-described operation is related to passive IC tags incorporating no battery, active IC tags incorporating a battery may be used.

In the present embodiment, as depicted in FIG. 1, a plurality of antennas ANT connected to the reader 200 take charge of the logical OR area of the reading regions of the antennas ANT as determination areas A1 and A2. The example depicted in FIG. 1 depicts a state in which as the reading region of the IC tags 10 passing through a gate G1, the determination area A1 is formed by the two antennas ANT1 and ANT2. The same applies to the determination area A2 for reading the IC tags 10 passing through a gate G2.

While one determination area is under the charge of two antennas ANT as described above in the present embodiment, one determination area may be under the charge of one antenna ANT, or one determination area may be under the charge of three or more antennas.

Moreover, while the four antennas ANT1 to ANT4 are managed by the single reader 200 in the present embodiment, the number of antennas and the number of readers may be set as appropriate.

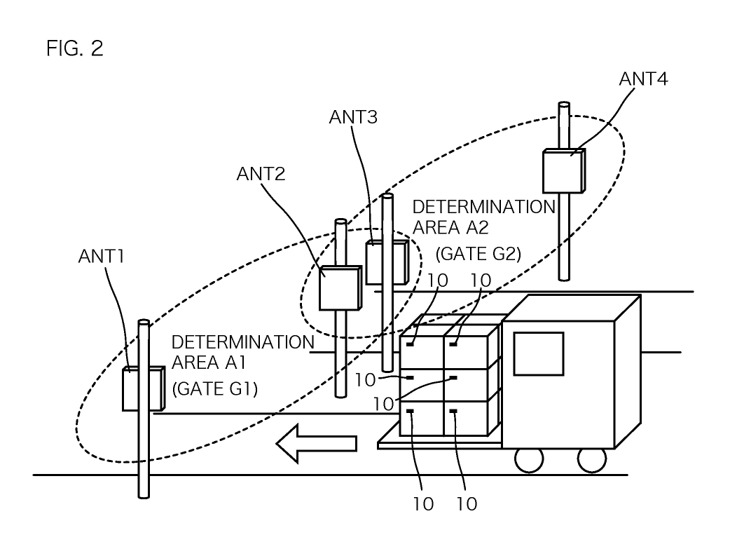

FIG. 2 is a schematic view of assistance in explaining concrete examples of the determination areas A1 and A2. The determination area A1 is, for example, the gate G1 through which pass forklifts and platform trucks carrying articles to which the IC tags 10 are attached. The same applies to the determination area A2.

For example, in a distribution center or the like, a plurality of gates G1 and G2 are set to load articles on trucks the destinations of which are different, and the antennas ANT1 to ANT4 are set to read the IC tags 10 at the gates G1 and G2. The identification information of the gates G1 and G2 is managed by the reader 200 and the host server 100 as the determination areas A1 and A2.

When a forklift or a platform truck carrying articles to which the IC tags 10 are attached passes through the gate G1, the IC tags 10 not only are read by the antennas ANT1 and ANT2 but also can be read by the antenna ANT4. Moreover, when a forklift or a platform truck carrying articles to which the IC tags 10 are attached passes through the gate G2, the IC tags 10 not only are read by the antennas ANT3 and ANT4 but also can be read by the antenna ANT1.

Therefore, in the present application, as described later, similarity determination using the reference data of the reading pattern is performed to thereby determine which of the gates G1 and G2 the forklift, the platform truck or the like passed through.

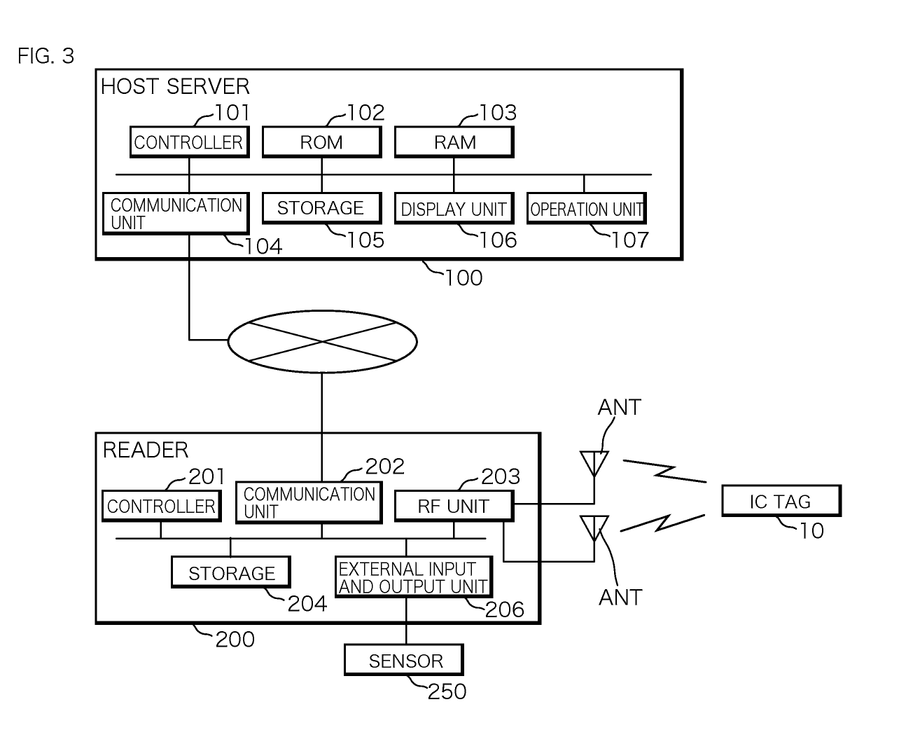

FIG. 3 is a block diagram of assistance in explaining the hardware structures of the host server 100 and the reader 200. The host server 100 is provided with a controller 101, a ROM (read only memory) 102, a RAM (random access memory) 103, a communication unit 104, a storage 105, a display unit 106 and an operation unit 107 which are interconnected through a bus.

The controller 101 is provided with a CPU (central processing unit) or an MPU (micro processing unit). When an MPU is provided, there are cases where the ROM 102 and the RAM 103 are incorporated in the controller 101.

According to predetermined timing, the controller 101 reads a computer program stored in the ROM 102 or the storage 105 onto the RAM 103 as appropriate for execution, and controls the operations of the above-mentioned hardware.

The ROM 102 pre-stores a computer program necessary for implementing the determination method of the present application and a computer program for operating the above-mentioned hardware.

The RAM 103 is, for example, a DRAM (dynamic RAM), an SRAM (static RAM) or a flash memory, and temporarily stores various pieces of data (for example, computational results, read data, various parameters) generated when a computer program is executed by the controller 101.

The communication unit 104 performs data communication with the reader 200 through a wired or wireless network, and receives data of the IC tags 10 read by the reader 200.

The operation unit 107 is provided with an input interface necessary for the operator to operate the host server 100. The display unit 106 is, for example, a liquid crystal display, and displays, in response to an instruction from the controller 101, the operating condition of the host server 100, information inputted through the operation unit 107 and information of which the operator is to be notified.

The display unit 106 and the operation unit 107 provide an interface with the operator. The host server 100 may perform operation input from another apparatus and output to another apparatus through a network, and is not necessarily provided with the display unit 106 and the operation unit 107.

The storage 105 is a nonvolatile storage device such as a hard disk or a flash memory. The storage 105 stores the reference data collected from the reader 200 and the like. While in the present embodiment, a computer program for implementing the determination method of the present application and a computer program for operating the hardware are stored in the ROM 102, these computer programs may be stored in the storage 105.

Next, the hardware structure of the reader 200 will be described. The reader 200 is provided with a controller 201, a communication unit 202, an RF unit 203, a storage 204 and an external input and output unit 206 which are interconnected through a bus.

The antennas ANT obtaining data from the IC tags 10 are connected to the RF unit 203. In the present embodiment, the antennas ANT1 to ANT4 are connected to the RF unit 203 of the reader 200.

The controller 201 of the reader 200 performs radio communication with the IC tags 10 through the RF unit 203 and the antennas ANT according to an operation procedure pre-stored in the storage 204. The storage 204 is a nonvolatile storage device such as a hard disk or a flash memory.

The external input and output unit 206 provides an interface for receiving an input from a sensor 250 such as an optical sensor or a tactile sensor and outputting a signal to the controller of an external device such as a PLC (programmable logic controller). By the sensor 250 detecting the passage of an article or a person, the reader 200 can recognize the passage of the article or the person through the external input and output unit 206, and the start and end of tag reading and the like can be controlled.

The reader 200 performs data transmission and reception with the IC tags 10 by the following procedure. The reader 200 first performs a search (inventory) for the IC tags 10 that are present in the readable areas of the antennas ANT. That is, the reader 200 outputs a search command encoded radio signal from the antennas ANT. The IC tags 10 having received the search command transmitted by the reader 200 become operable by the parts thereof being supplied with a voltage, and then, transmit their own identification data (tag ID) to the reader 200 as a response to the search command.

By doing this, the reader 200 can identify the tag IDs of the IC tags 10, and data transmission and reception between the reader 200 and the IC tags 10 is enabled.

In a case where a plurality of IC tags 10 are present in the communication possible area of the antennas ANT when the reader 200 transmits the search command, since a plurality of IC tags 10 transmit a response to the search command at the same time, the responses interfere with each other, so that a collision situation can occur where the reader 200 may not receive the responses.

To avoid this, the reader 200 and the IC tags 10 are provided with a collision avoidance function. When a collision occurs, temporary suppression of responses from the IC tags 10 and the like are performed according to a collision avoidance protocol determined between the reader 200 and the IC tags 10, and the reader 200 receives a response containing a tag ID from one IC tag 10 that remains finally, thereby identifying the IC tag 10. When an IC tag 10 having made no response remains, a similar collision avoidance procedure is followed according to a command continuously transmitted from the reader 200, and the tag IDs are identified one by one. As a result, the reader 200 can obtain all the tag IDs of the IC tags 10 that can make a response.

When the IC tags 10 include data related to an article or the like in addition to the tag ID, by further performing transmission and reception of a data reading command and a data writing command between the reader 200 and the IC tags 10, data reading and writing can be performed.

The reader 200 autonomously repeats search command transmission according to a previously specified condition. Every time the search command is received, the IC tags 10 transmit data that they store. Consequently, if the IC tags 10 that are present in the reading possible areas of the connected antennas ANT make a response every time the search command is transmitted and there is no problem with the radio wave environment, the reader 200 receives data of the number of responses of the IC tags 10.

The reader 200 and the host server 100 perform unnecessary tag reading filtering by using the time-series pattern repetitively received for each tag ID.

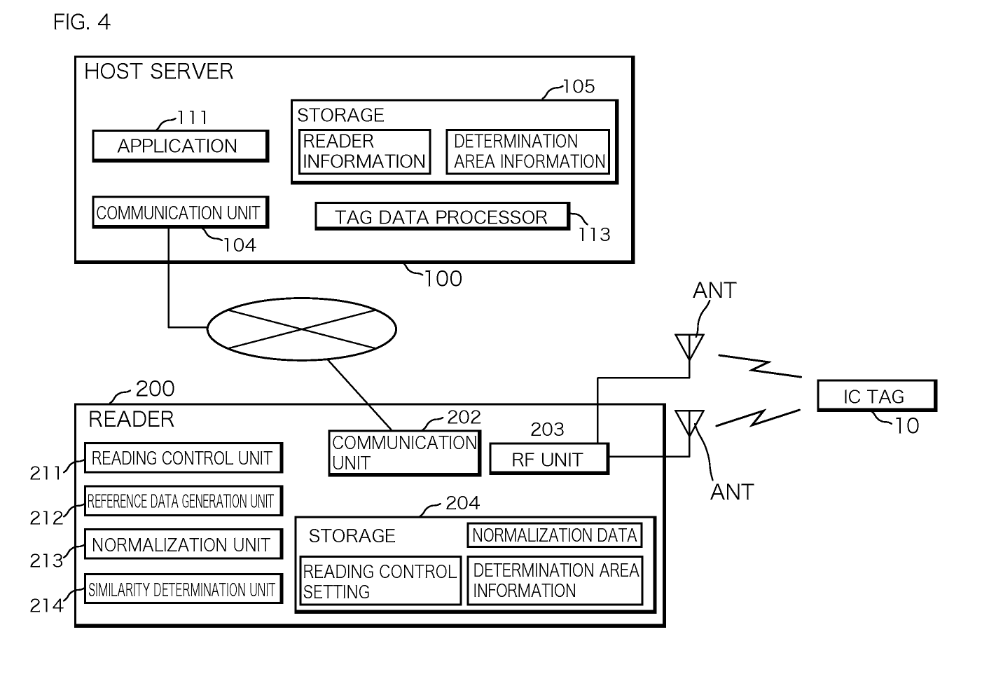

FIG. 4 is a block diagram of assistance in explaining the functional structures of the host server 100 and the reader 200. An application 111 stored in the host server 100 performs, for example, processing for various operations such as production, physical distribution and inventory management by using the information of the tag read by the reader 200.

A tag data processor 113 plays a role in changing data such as the tag ID reported by the reader 200 into a format used by the application 111, and delivering it to the application 111.

The storage 105 stores information on the reader 200 from which the host server 100 can receive tag data (reader information) and information on the determination area under the charge of the reader 200 (determination area information).

The communication unit 104 performs communication with the reader 200 by procedures conforming to various wired or wireless protocols.

The reader 200 autonomously operates according to the reading control setting set prior to operation, and reads the IC tags 10.

The reading control setting is stored in the storage 204 of the reader 200, and in the reading control setting, the following are described: one or more than one antenna ANT used and the order thereof; the number of times of repetitive search command transmission from each antenna ANT and the time thereof; and when reading and writing of data other than IDs is performed for the read tag IDs, the specification of the reading and writing command.

A reading control unit 211 loads the contents of the reading control setting from the storage 204, performs control so that a command to perform a search (inventory) for the IC tags 10 is transmitted to the RF unit 203 corresponding to each antenna ANT according to the described control procedure, and reads the responses from the IC tags 10.

A reference data generation unit 212 generates reference data for filtering from information such as a reference pattern which is an ideal reading pattern collected by the reader 200 in advance. The generated reference data is recorded in the storage 105.

A normalization unit 213 processes tag responses obtained at the time of operation as the time-series data of each tag ID, corrects the time-series data by normalization described later, and then, passes it to a similarity determination unit 214.

The similarity determination unit 214 makes a comparison between the time-series data passed from the normalization unit 213 and the reference data stored in the storage 204, and calculates the similarity to each cluster data. The procedure of the similarity determination performed by the similarity determination unit 214 will be described later in detail.

Next, the time-series data handled by the normalization unit 213 will be described.

According to the reading control setting stored in the storage 204, the reader 200 repetitively issues a search (inventory) command while repetitively using one or more than one antenna ANT. The results of the responses to the search commands are passed to the normalization unit 213 together with information such as the antenna used, a list of the read tag IDs, the number of lists and the time it took to read the tag IDs (normally, several tens to hundreds of milliseconds). At this time, the results of the responses to the search commands are temporarily stored in a memory in the normalization unit 213 as data in chronological order in a state of being grouped for each determination area and for each tag ID. The data in chronological order stored in the memory of the normalization unit 213 will be referred to as reading pattern.

The normalization unit 213 obtains the sum of the numbers of IC tags read in the readings for each antenna ANT, calculates the average number of times of reading for each antenna ANT by dividing the sum by the number of times of reading in which at least one IC tag 10 is read, and stores the result into an internal memory.

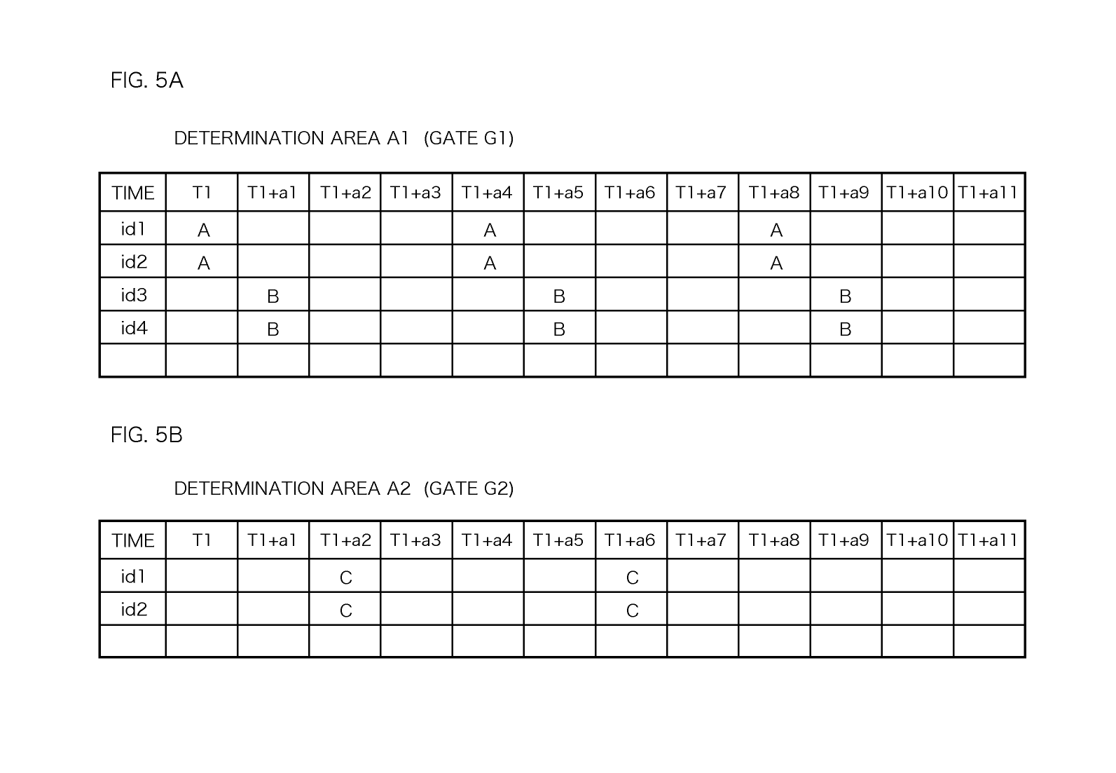

FIGS. 5A and 5B are schematic views depicting examples of reading patterns. FIG. 5A depicts an example of the reading pattern in the determination area A1 (gate G1). FIG. 5B depicts an example of the reading pattern in the determination area A2 (gate G2). As mentioned above, in the gate G1, the two antennas ANT1 and ANT2 take charge of the determination area A1, whereas in the gate G2, the two antennas ANT3 and ANT4 take charge of the determination area A2.

In each reading pattern, T1, T1+a1, . . . , and T1+a11 in the direction of rows (lateral axis) represent a time series, and indicate the times when the reader 200 issues the search command. In the present embodiment, the reader 200 repetitively issues the search command while switching the antenna issuing the search command at each time in the order of the antennas ANT1, ANT2, ANT3 and ANT4. The search command is not always issued at regular intervals but issued at appropriate times controlled by the controller 201 of the reader 200. Here, a1, a2, . . . , and all are times of approximately several tens of seconds.

In the left end of the reading pattern in the direction of columns (longitudinal axis), the tag IDs of the read IC tags 10 are listed. In the examples depicted in FIGS. 5A and 5B, it is indicated that the IC tags 10 having tag IDs id1 to id4 were read.

The reference designations A to C depicted in cells of the reading patterns are symbols representative of the antennas ANT1, ANT2 and ANT3, respectively. While the symbol representative of the antenna ANT4 is D, in the examples depicted in FIGS. 5A and 5B, it is indicated that reading by the antenna ANT4 was not performed. The blank cells indicate that reading of the IC tags 10 was not performed.

The reading pattern depicted in FIG. 5A is a pattern in which as a result of the antenna ANT1 issuing the search command at times T1, T1+a4 and T1+a8, the IC tag 10 having the tag ID id1 and the IC tag 10 having the tag ID id2 were read, and as a result of the antenna ANT2 issuing the search command at the times T1+a1, T1+a5 and T1+a9, the IC tag 10 having the tag ID id3 and the IC tag 10 having the tag ID id4 were read. On the other hand, the reading pattern depicted in FIG. 5B is a pattern in which as a result of the antenna ANT3 issuing the search command at times T1+a2 and T1+a6, the IC tag 10 having the tag ID id1 and the IC tag 10 having the tag ID di2 were read.

To express each row of the reading pattern as a symbol string, the blank cells may be expressed as underscores; for example, the row of id1 in the determination area A1 may be expressed as “A_A_A_”.

When the antenna transmission power is changed in two levels, the antenna may be represented by a capital letter like “A” when the output is high and by a lower-case letter like “a” when the output is low.

While the time series is taken in the direction of rows (lateral axis) in the examples of FIGS. 5A and 5B, the number of times of search command issuance may be provided on the lateral axis. In the following description, to avoid complexity, the number of times of search command issuance is provided on the lateral axis.

In the present embodiment, the reading pattern for each tag that is read at the time of operation is compared with the reference data collected and stored in advance and the similarity is obtained, thereby deciding the determination area that seems most probable.

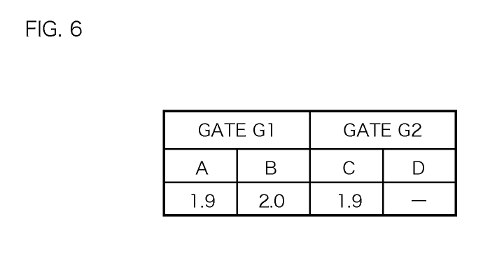

FIG. 6 is a schematic view depicting an example of the average number of times of reading by the antennas ANT. In the example depicted in FIG. 6, it is indicated that the average number of times of reading by the antenna ANT1 included in the gate G1 is 1.9 times and the average number of times of reading by the antenna ANT2 is 2.0 times. It is also indicated that the average number of times of reading by the antenna ANT3 included in the gate 2 is 1.9 times and reading by the antenna ANT4 was not performed.

Next, the reference data will be described. When the reference data is generated, each reader 200 is operated as at the time of operation, and data is collected while articles to which IC tags are attached are placed or moved in a loading condition similar to that at the time of operation. In each determination area, reading is performed a plurality of times (for example, five to ten times), and the host server 100 generates the reference data based on the collected data.

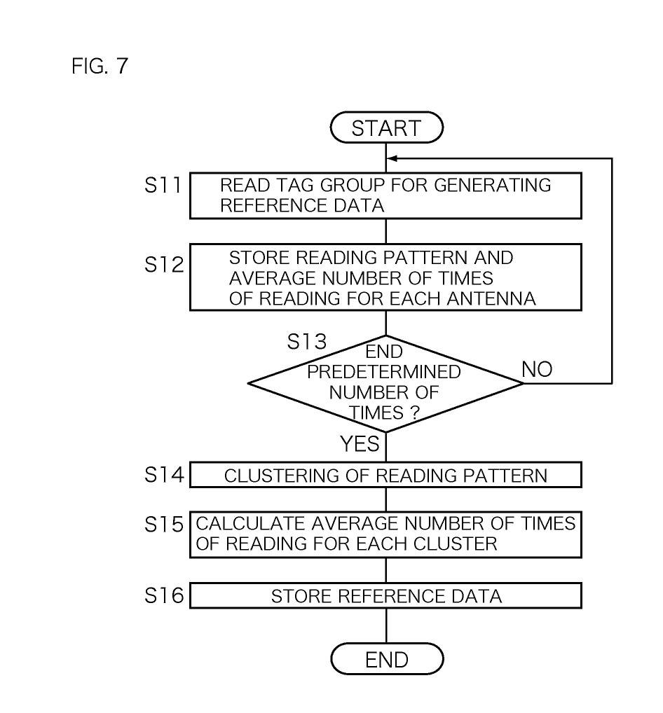

FIG. 7 is a flowchart depicting the reference data generation procedure. First, a tag group for reference data generation is prepared in advance. Specifically, a tag group for reference data generation is formed by loading a plurality of articles to which tags are attached as at the time of operation, and the tag group is moved by movement means similar to that at the time of operation or placed. As the movement means, a forklift, a platform truck, a conveyor or the like may be used.

The reader 200 reads the tag group for reference data generation under similar conditions (the movement speed, etc.) to those at the time of normal operation (at S11). At this time, the reference data generation unit 212 provides an instruction to the reading control unit 211 to continuously perform a search (inventory) for the IC tags 10.

The result of the search for the IC tags 10 is returned to the reference data generation unit 212. The reference data generation unit 212 calculates the reading pattern for each tag ID and the average number of times of reading for each antenna based on the search result, and temporarily stores them (at S12).

The processing of passing the tag group for reference data generation through the gates and reading the IC tags is repeated a predetermined number of times. The reference data generation unit 212 calculates the reading pattern and the average number of times of reading every time reading is executed, and stores the result of the calculation for each tag ID and for each determination area.

After the processing of at S12, the reading control unit 211 of the reader 200 determines whether a predetermined number of times of reading has been finished or not (at S13). When the predetermined number of times of reading has not been finished (S13: NO), the process is returned to S11.

When the predetermined number of times of reading has been finished (S13: YES), the reader 200 performs reading pattern clustering for each determination area (at S14). For the clustering, various known clustering methods may be used. For example, as the method of calculating the similarity serving as the reference, the following method may be used: First, the symbol strings of two reading patterns are compared with each other. When both are “_” or one is “_{—}”, 0 is added, when they are the same symbol other than “_” (for example, when both are “A” or both are “B”), 1 is added, and when they are different symbols, −1 (minus 1) is added. Then, the obtained value is divided by the overall number of times of reading to thereby obtain a provisional similarity. Then, the similarity calculation is performed while the reading pattern is shifted, and the highest similarity is obtained as the similarity between the two reading patterns.

As described above, the similarity between the reading patterns is calculated and clustering is performed to generate some typical reading pattern clusters.

After performing clustering, the reference data generation unit 212 of the reader 200 calculates the average number of read tags in each cluster (at S15). That is, in each cluster, the reference data generation unit 212 obtains the average for each antenna with respect to the average number of read tags for each antenna associated with each reading pattern included in the cluster. In ordinary cases, since the reading patterns of all the reading trials are included in a cluster, the average of the average numbers of times of reading is obtained for each antenna ANT.

After performing the above-described processing, the reference data generation unit 212 stores the clusters and the average numbers of read tags for the antennas associated with the clusters into a memory as the reference data (at S16).

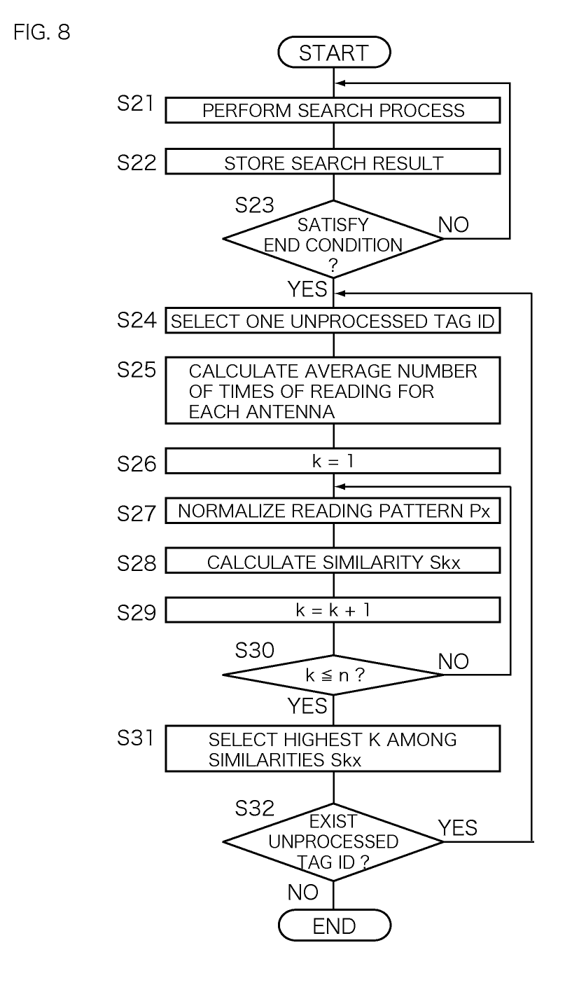

Next, the tag reading procedure at the time of operation will be described. FIG. 8 is a flowchart depicting the tag reading procedure at the time of operation. The reading control unit 211 of the reader 200 receives a reading start instruction from the host server 100, and according to the reading control setting stored in the storage 204, repetitively performs the search (inventory) in each determination area by successively using the antennas ANT connected to the reader 200 (at S21).

A structure may be adopted in which the passage of a person or an article is detected by using the sensor 250 and a search start trigger is provided. In this case, the input of the reading start instruction from the host server 100 may be omitted.

The reading control unit 211 repetitively executes the search for the IC tags 10 and the report of the search result to the normalization unit 213. While waiting for the search result (the result of reading of the IC tags 10) reported by the reading control unit 211, the normalization unit 213 temporarily stores the search result reported by the reading control unit 211 until a provided end condition is satisfied (at S22). Here, that the tag reading by the reader 200 is not performed for a predetermined period of time can be used as the end condition.

Moreover, that neither a person nor an article passing through the determination area is detected by using the sensor 250 may be used as the end condition.

The normalization unit 213 determines whether the end condition is satisfied or not (at S23). When the end condition is not satisfied (S23: NO), the process is returned to S21.

When determining that the end condition is satisfied (S23: YES), the normalization unit 213 selects one unprocessed tag ID from among the read tag IDs (at S24), and then, generates a reading pattern Px of the IC tag 10 having the tag ID and calculates the average number of read tags for each antenna ANT (at S25).

For example, when the reading of the IC tags 10 is alternately performed by the two antennas ANT1 and ANT2, the average numbers n_a and n_b of tags read by the antennas ANT1 and ANT2 are calculated by the following expression:

$$n\_a = ( {\sum }_{j = 0}^{u} n i ) / c\_a ( i = 1 + j \times 2 ) \\ n\_b = ( {\sum }_{j = 0}^{u - 1} n i ) / c\_b ( i = 2 + j \times 2 ) \qquad [ Expression 1 ]$$

Here, ni is the number of read tags in the result of the i-th reading, c_a is the number of times of tag reading performed by the antenna ANT1, c_b is the number of times of tag reading performed by the antenna ANT2, and u is the integer part of the quotient when the total number of times of tag reading processed in the present normalization is divided by two.

While the expression 1 expresses the average number of tags read by each antenna when the number of antennas is two, the average number of read tags can be calculated by a similar calculation method also when the number of antennas is three or more.

After the processing of at S25, the normalization unit 213 selects one cluster Ck from the reference data. Here, the initial value is k=1, and the total number of clusters of the reference data is n (at S26).

Then, the normalization unit 213 normalizes the reading pattern Px by using the cluster Ck of the reference data (at S27). Details of the normalization executed at S27 will be described later. The resulting reading pattern N(Px) normalized by the normalization unit 213 is provided to the similarity determination unit 214 of the reader 200.

The similarity determination unit 214 calculates the similarity Skx between the reading pattern N(Px) normalized by the normalization unit 213 and the cluster Ck (at S28). As the procedure of calculating the similarity Skx, a procedure similar to that at the time of reference data generation may be used. That is, the symbol string of the normalized reading pattern N(Px) and the symbol string of the cluster Ck are compared with each other. When both are “_” or one is “_{—}”, 0 is added, when they are the same symbol other than “_” (for example, both are “A” or both are “B”), 1 is added, and when they are different symbols, −1 (minus 1) is added. Then, the obtained value is divided by the overall number of times of reading to thereby obtain a provisional similarity. Then, the similarity calculation is performed while the targets of the comparison are shifted in the direction of the time axis, and the highest similarity is obtained as the similarity Skx between the two.

When the calculation of the similarity Skx by the similarity determination unit 214 is ended, the normalization unit 213 increments the value of the counter k by one (at S29), and determines whether a condition k≦n is satisfied or not (at S30). When the condition k≦n is not satisfied (S30: NO), the process is returned to S27.

When the condition k≦n is satisfied (S30: YES), the normalization unit 213 selects the highest k among the similarities Skx (at S31).

Then, the normalization unit 213 determines whether there is an unprocessed tag ID or not (at S32). When there is an unprocessed tag ID (S32: YES), the process is returned to S24. When there is no unprocessed tag ID (S32: NO), the processing by this flowchart is ended.

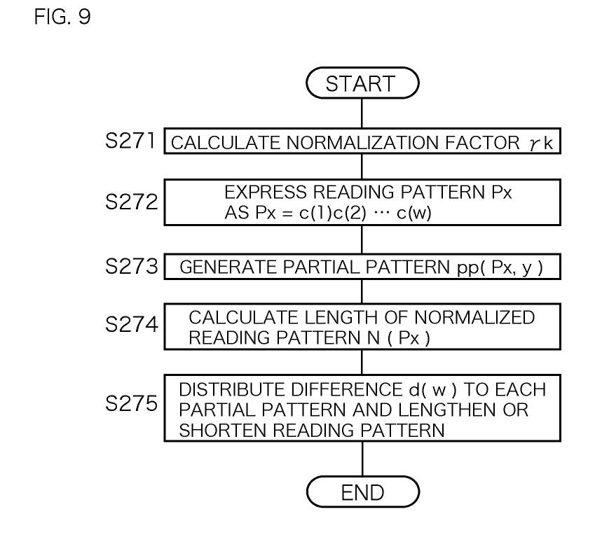

The normalization unit 213 performs the normalization of the reading pattern selected by the following procedure: FIG. 9 is a flowchart depicting the normalization procedure. In the normalization, it is assumed that the number of times of reading within the same time period is inversely proportional to the average number of read tags when the fluctuation is within a given range.

When the average numbers of read tags for each antenna with respect to the reading pattern Px and the cluster Ck are (n_a, n_b) and (nk_a, nk_b), respectively, a normalization factor γk is calculated as follows as the reciprocal of the ratio of the average number of read tags of Ck to Pk (at S271):

γk=(n_{—}a+n_{—}b)/(nk_{—}a+nk_{—}b) [Expression 2]

The reason why the normalization factor γk in the present embodiment is the reciprocal of the ratio of the average number of read tags of Ck to Pk is that the average number of times of reading and average number of read tags that are to be normalized are inversely proportional to each other.

Using this normalization factor γk, a normalized reading pattern N(Px) obtained by normalizing the reading pattern Px is generated by the following procedure:

First, the reading pattern Px where the total number of times of reading is w (hereinafter, referred to as reading pattern Px with a length w) is expressed as a symbol string like Px=c(1)c(2)c(3) . . . c(w) (at S272).

Here, a symbol such as “A” or “B” to identify the antenna ANT that performed the reading or a symbol “_” representing that no reading was performed is substituted for each of c(1), c(2), c(3), and c(w). Here, for c(1), a symbol other than “_” is substituted.

Then, a partial pattern pp(Px,y) is generated from the reading pattern Px (at S273). When the number of antennas is s (normally, operation is performed with s≦4), the partial pattern pp(Px,y) of the y-th antenna (1≦y≦s) is given as follows:

$$pp ( Px , y ) = \{ \begin{matrix}c ( y ) c ( y + s ) c ( y + 2 s ) … c ( y + h \times s ) ; & y \leq r \\ c ( y ) c ( y + s ) c ( y + 2 s ) … c ( y + ( h - 1 ) \times s ) ; & y > r\end{matrix} \qquad [ Expression 3 ]$$

Here, h=int(w/s) and r=mod(w, s), where int(w/s) represents the integer part (that is, the part that is left when the fractional part is discarded) of a real value w/s and mod(w,s) represents the remainder of w modulo s.

For example, when the reading pattern Px is “A_ABA_A_A_A”, the partial pattern pp(Px, 1) is expressed as “AAAAAA”, and the partial pattern pp(Py, 2) is expressed as “_B_”. Here, generally, it does not mean that when y=1, the corresponding antenna is the antenna ANT1 (symbol string “A”) and when y=2, the corresponding antenna is the antenna ANT2 (symbol string “B”).

When the length (the number of characters) of the reading pattern Px is w, the length w′ of the normalized reading pattern N(Px) is calculated as follows (at S274): In the present embodiment, since a relationship is assumed in which the number of times of reading (length) decreases as the number of read tags increases, by multiplying the length w of the reading pattern Px by γk representative of the reciprocal of the ratio of the average number of read tags, the length w′ after normalization is obtained as follows:

w′=int(w×γk) [Expression 4]

The difference d(w)=w′−w between the length w of the reading pattern Px and the length w′ of the normalized reading pattern N(Px) is distributed to the partial patterns, and the reading pattern Px is lengthened or shortened as described below (at S275).

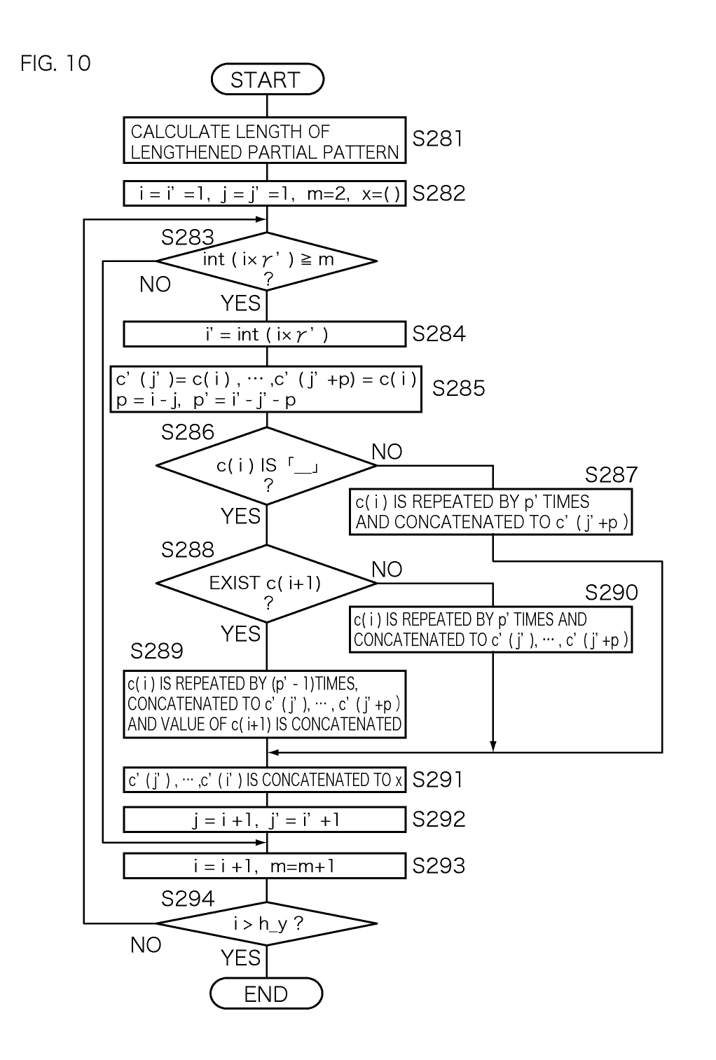

Next, the extension of the reading pattern Px by the normalization unit 213 will be described. FIG. 10 is a flowchart depicting the procedure of lengthening the reading pattern Px. When d(w)>0, the normalization unit 213 executes the processings of the following steps to lengthen the reading pattern Px. First, when h′=int((d(w)+r)/s), r′=mod(d(w)+r, s) and the length of the partial pattern pp(Px, y) of the y-th antenna ANT (1≦y≦s) is h_y, the length h′_y of a new partial pattern pp′(Px, y) after the extension of the partial pattern pp(Px, y) is calculated as follows (at S281):

$${h}^{′} \_y = \{ \begin{matrix}h\_y + {h}^{′} ; & y \leq r \text{\&} y \leq {r}^{′} \\ h\_y + {h}^{′} - 1 ; & y \leq r \text{\&} y > {r}^{′} \\ h\_y + {h}^{′} + 1 ; & y > r \text{\&} y \leq {r}^{′} \\ h\_y + {h}^{′} ; & y > r \text{\&} y > {r}^{′}\end{matrix} \qquad [ Expression 5 ]$$

Here, if γ′=(h′_y)/(h_y) and pp(Px,y)=c(1)c(2)c(3) . . . c(h_y), pp′(Px,y) is structured as follows:

First, as the initial value, i=i′=1, j=j′=1, m=2, and x=( ) (null character string) are set (at S282).

Then, whether a condition int(i×γ′)≧m is satisfied or not is determined (at S283). When the condition is satisfied (S283: YES), after setting i'=int(i×γ′) (at S284), c(j), . . . , c(i) is converted to c′(j′), . . . , c′(i′) by the following procedure:

When the condition int(i×γ′)≧m is not satisfied (S283: NO), the process is shifted to the processing of S293 described later.

Here, c′(j′)=(j), . . . , c′(j′+p)=c(i) is set, and p=i−j and p′=i′−j′−p are set (at S285).

Whether c(i) is “_” or not is determined (S286). When c(i) is not “_” (S286: NO), c(i) is repeated by p′ times and concatenated to c′(j′+p) (at S287).

When c(i) is “_” (S286: YES) and c(i+1) is present (S288: YES), after c(i) is repeated by (p′−1) times and concatenated to c′(j′+p), the value of c(i+1) is concatenated lastly (at S289).

When c(i) is “_” (S286: YES) and c(i+1) is absent (S288: NO), c(i) is repeated by p′ times and concatenated to c′(j′) . . . c′(j′+p) (at S290).

After the processings of at S287, S289 and S290, c′(j′) . . . c′(i′) is concatenated to x (at S291). That is, x=x·c′(j′) . . . c′(i′) is created.

Then, after setting j=i+1 and j′=+1 (at S292), the values of i and m are incremented by one (at S293), and whether i>h_y or not is determined (at S294).

When i>h_y (S294: NO), the process is returned to S283, and when i>h_y, the processing by this flowchart is ended.

While the extension of the reading pattern Px has been described above, when the reading pattern Px is shortened, the shortened reading pattern N(Px) can be obtained by a procedure similar to that of the extension processing. The shortening of the reading pattern Px is executed when d(w)<0.

Here, when d(w)=0, N(Px)=Px. That is, when no conversion occurs on the length of the reading pattern between before and after normalization, the reading pattern Px before normalization is made the normalized reading pattern N(Px) as it is.

As described above, by executing the processing in which the extension of the reading pattern Px is made when d(w)>0, the shortening of the reading pattern Px is made when d(w)<0 and the same reading pattern is set as the normalized reading pattern when d(w)=0, the normalization unit 213 generates the normalized reading pattern N(Px). By the procedure as described above, the reading pattern N(Px) resulting from the extension or the shortening of the reading pattern Px can be obtained while the balance of the character string of the original reading pattern Px is maintained.

### Second Embodiment

In the first embodiment, the reading pattern obtained at the time of operation is normalized on the assumption that the movement speed of the articles to which the IC tags 10 are attached is substantially the same between at the time of operation and at the time of reference data collection. However, since the movement speed of the articles can be estimated based on the data obtained by the reader 200, the reading pattern can also be normalized in consideration of the movement speed.

In the second embodiment, a structure will be described in which the reading pattern is normalized in consideration of the movement speed of the articles to which the IC tags 10 are attached.

The movement speed of the articles can be estimated by measuring the time interval between the start and end of reading within the antenna communication range from the reading result list provided by the reading control unit 211. However, this is based on a premise that the articles are moving at a constant speed.

When the time interval between the start and end of reading when the reference data is obtained is T_k and the time interval between the start and end of reading at the time of operation is T, the ratio αk between the time intervals can be calculated by αk=T_k/T.

When the length (the total number of times of reading) of the reading pattern Px obtained by tag reading is w, the reading pattern Px is lengthened or shortened so that the length after normalization is w′=int(w×γk×αk). Here, γk is the factor representative of the reciprocal of the ratio of the average number of read tags at the time of reference data generation and at the time of operation described in the first embodiment.

The method of lengthening or shortening the reading pattern Px so that the length after normalization is w′ is completely the same as that of the first embodiment. That is, the difference between the length w of the reading pattern Px and the length w′ of the normalized reading pattern N(Px) is distributed to the partial patterns generated from the reading patter Px, and the reading pattern Px is lengthened or shortened.

In the second embodiment, since the premise is unnecessary that the movement speed of the articles to which the IC tags 10 are attached is substantially the same between at the time of reference data collection and at the time of operation, determination accuracy degradation can be prevented regardless of the operation form.

### Third Embodiment

While in the first embodiment, the system is structured so that the processings of the reference data generation, the reading pattern normalization and the similarity determination are performed on the side of the reader 200, the system may be structured so that these processings are performed on the side of the host server 100.

In the third embodiment, a structure will be described in which the host server 100 performs the processings of the reference data generation, the reading pattern normalization and the similarity generation based on the result of detection of the IC tags 10 obtained through the reader 200.

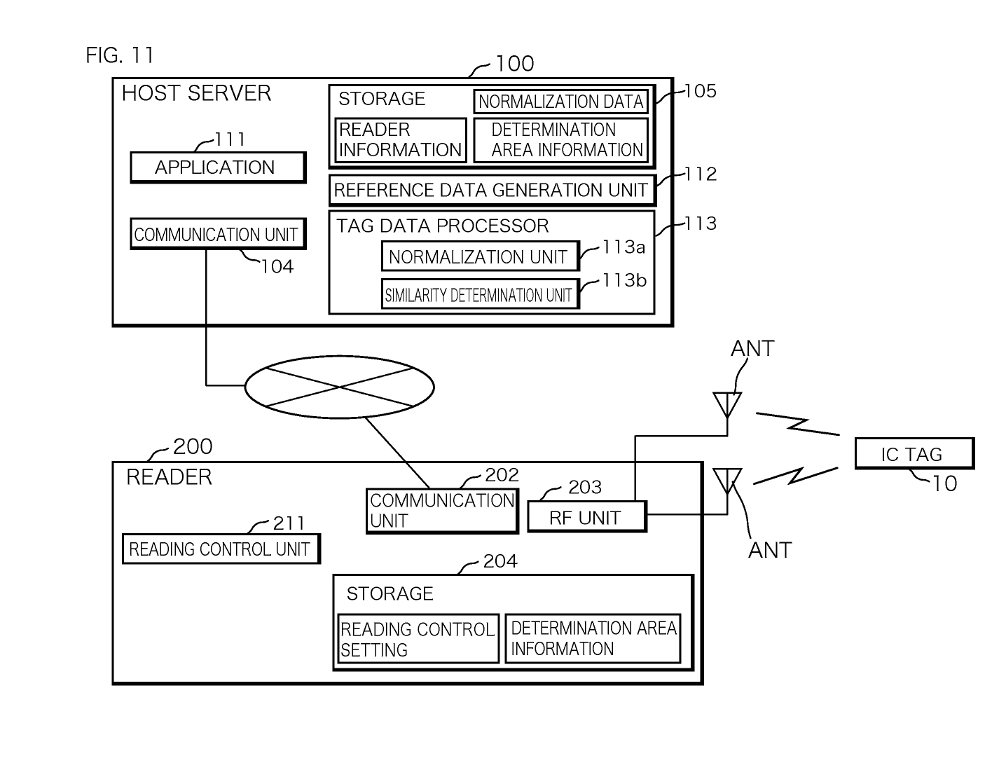

FIG. 11 is a block diagram of assistance in explaining the functional structures of the host server 100 and the reader 200 according to the third embodiment. The reader 200 autonomously operates according to the reading control setting, and reads the IC tags 10. The reading control unit 211 loads the contents of the reading control setting from the storage 204, performs control so that the command to make a search (inventory) for the IC tags 10 is transmitted to the RF unit 203 corresponding to each antenna ANT according to the described control procedure, and reads the responses from the IC tags 10.

In the present embodiment, the information of the read tag IDs is transmitted to the host server 100 through the communication unit 202.

The host server 100 is provided with a reference data generation unit 112 that generates the reference data based on the data of the tag IDs from the reader 200 received through the communication unit 104. The reference data generation method is completely the same as that of the first embodiment.

A tag data processing unit 113 of the host server 100 is provided with a normalization unit 113a that normalizes the data of the tag IDs from the reader 200 newly received through the communication unit 104 and a similarity determination unit 113b that determines the similarity to the reference data based on the normalized data. The normalization executed by the normalization unit 113a and the similarity determination executed by the similarity determination unit 113b are completely the same as the normalization and the similarity determination executed by the reader 200 of the first embodiment.

According to the second embodiment, the structure of the reader placed on the site can be simplified, so that placement flexibility improves.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification related to a showing of the superiority and inferiority of the invention. Although the embodiments of the present inventions have been described in detail, it should be understood that the various changes, substitutions, and alternations could be made hereto without departing from the spirit and scope of the invention.

What is claimed is:

1. A determination apparatus comprising:
a data obtaining unit that obtains data from a detector that outputs data in time series, in accordance with a result of detection of a detection target;
a data correction unit that compares reference data indicative of data to be outputted by the detector when the detection target passed through a specific area with the data obtained by the data obtaining unit, and corrects the data obtained by the data obtaining unit so that a data length of the data is equal to a data length of the reference data;
a similarity determination unit that determines a similarity between the data corrected by the data correction unit and the reference data; and
a determination unit that determines whether the detection target passed through the specific area or not based on a result of the determination by the similarity determination unit.

2. The determination apparatus according to claim 1, wherein the data correction unit calculates a ratio between a value indicative of a detection condition of the detection target when the reference data is generated and a value indicative of a detection condition of the detection target when the data obtaining unit newly obtains data, and normalizes the data newly obtained by the data obtaining unit, by using the calculated ratio.

3. The determination apparatus according to claim 2, wherein the values indicative of the detection conditions, which are targets of the comparison by the data correction unit, are each the number of detection targets detected by the detector.

4. The determination apparatus according to claim 3, wherein the data correction unit lengthens or shortens the data according to the calculated ratio.

5. The determination apparatus according to claim 4, wherein the data correction unit divides the data into a plurality of pieces in a direction of time to generate partial data, and lengthens or shortens each piece of the generated partial data according to the calculated ratio.

6. The determination apparatus according to claim 2, wherein the values indicative of the detection conditions, which are targets of the comparison by the data correction unit, are times elapsed for the detection target to pass through the specific area.

7. The determination apparatus according to claim 6, wherein the data correction unit lengthens or shortens the data according to the calculated ratio.

8. The determination apparatus according to claim 7, wherein the data correction unit divides the data into a plurality of pieces in a direction of time to generate partial data, and lengthens or shortens each piece of the generated partial data according to the calculated ratio.

9. A determination system comprising:
a detector that outputs data in time series, in accordance with a result of detection of a detection target; and
a determination apparatus which comprises:
a data obtaining unit that obtains the data outputted by the detector;
a data correction unit that compares reference data indicative of data to be outputted by the detector when the detection target passed through a specific area with the data obtained by the data obtaining unit, and corrects the data obtained by the data obtaining unit so that a data length of the data is equal to a data length of the reference data;
a similarity determination unit that determines a similarity between the data corrected by the data correction unit and the reference data; and
a determination unit that determines whether the detection target passed through the specific area or not based on a result of the determination by the similarity determination unit.

10. The determination system according to claim 9, wherein the data correction unit calculates a ratio between a value indicative of a detection condition of the detection target when the reference data is generated and a value indicative of a detection condition of the detection target when the data obtaining unit newly obtains data, and normalizes the data newly obtained by the data obtaining unit, by using the calculated ratio.

11. The determination system according to claim 10, wherein the values indicative of the detection conditions, which are targets of the comparison by the data correction unit, are each the number of detection targets detected by the detector.

12. The determination system according to claim 11, wherein the data correction unit lengthens or shortens the data according to the calculated ratio.

13. The determination system according to claim 12, wherein the data correction unit divides the data into a plurality of pieces in a direction of time to generate partial data, and lengthens or shortens each piece of the generated partial data according to the calculated ratio.

14. The determination system according to claim 10, wherein the values indicative of the detection conditions, which are targets of the comparison by the data correction unit, are times elapsed for the detection target to pass through the specific area.

15. The determination system according to claim 14, wherein the data correction unit lengthens or shortens the data according to the calculated ratio.

16. The determination system according to claim 15, wherein the data correction unit divides the data into a plurality of pieces in a direction of time to generate partial data, and lengthens or shortens each piece of the generated partial data according to the calculated ratio.

17. A determination method comprising:
obtaining data from a detector that outputs data in time series, in accordance with a result of detection of a detection target;
comparing reference data indicative of data to be outputted by the detector when the detection target passed through a specific area with the data obtained from the detector;
correcting the obtained data so that a data length of the data is equal to a data length of the reference data based on a result of the comparison;
determining a similarity between the data obtained by the correction and the reference data; and
determining whether the detection target passed through the specific area or not based on a result of the determination.

18. A recording medium storing a computer program, wherein the computer program comprising:
causing a computer to obtain data from a detector that outputs data in time series, in accordance with a result of detection of a detection target;
causing the computer to compare reference data indicative of data to be outputted by the detector when the detection target passed through a specific area with the data obtained from the detector;
causing the computer to correct the obtained data so that a data length of the data is equal to a data length of the reference data based on a result of the comparison;
causing the computer to determine a similarity between the data obtained by the correction and the reference data; and
causing the computer to determine whether the detection target passed through the specific area or not based on a result of the determination.
